(19) United States
(12) Patent Application Publication
(10) Pub. No.: US 2008/0166501 A1
(43) Pub. Date: Jul. 10, 2008

(54) Pulsed Laser Deposition Method

(75) Inventor: Jari Ruuttu, Billnas (FI)

Correspondence Address: YOUNG & THOMPSON, 209 Madison Street, Suite 500, ALEXANDRIA, VA, 22314, US

(73) Assignee: PICODEON LTD OY, HELSINKI (FI)

(21) Appl. No.: 11/884,922

(22) PCT Filed: Feb. 23, 2006
(86) PCT No.: PCT/FI2006/000068

§ 371 Date: Oct. 11, 2007

(30) Foreign Application Priority Data
Feb. 23, 2005 (FI) 20050216
May 26, 2005 (FI) 20050558
May 26, 2005 (FI) 20050559

(51) Int. Cl. C03C 17/00; C23C 14/28; C04B 41/45

(52) U.S. Cl. 427/596; 427/597

(57) ABSTRACT

The invention relates to a method for coating a body of metal, glass, rock or plastic, in which the body is coated by laser ablation, with the body shifted in a material plasma fan ablated from a moving target in order to achieve a coating having as regular quality as possible. The invention also relates to the product produced by the method.

### FIELD OF THE INVENTION

This invention relates to a method for pulsed laser ablation deposition (PLD—Pulsed Laser Deposition), and to a product aiming at producing an optimal surface quality by ablation of a moving target in order to coat a moving substrate.

### STATE OF THE ART

The laser technology has made considerable progress over the recent years, and nowadays laser systems based on semi-conductor fibres can be produced with tolerable efficiency for use in cold ablation, for instance. Such lasers intended for cold ablation include picosecond lasers and phemto-second lasers. In terms of picosecond lasers, for instance, the cold-ablation range implies pulse lengths having a duration of 100 pico-seconds or less. Pico-second lasers differ from phemto-second lasers both with respect to their pulse duration and to their repetition frequency, the most recent commercial picosecond lasers having repetition frequencies in the range 1-4 MHz, whereas phemto-second lasers operate at repetition frequencies measured only in kilohertz. In the optimal case, cold ablation enables ablation of the material without the ablated material proper being subject to thermal transfers, in other words, the material ablated by each pulse is subject to pulse energy alone.

Besides a fully fibre-based diode-pumped semi-conductor laser, there are competitive lamp-pumped laser sources, in which the laser beam is first directed to a fibre and from there to the work site. According to the applicant's information by the priority date of the present application, these fibre-based laser systems are presently the only means of providing products based on laser ablation on any industrial scale.

The fibres of current fibre lasers and the consequently restrained beam effect set limits to the choice of materials that can be ablated. Aluminium can be ablated with a reasonable pulse effect as such, whereas materials less apt to ablation, such as copper, tungsten etc., require an appreciably higher pulse effect.

A second prior art feature comprises the scanning width of the laser beam. Linear scanning has been generally used in mirror film scanners, typically yielding a scanning line width in the range 30 mm-70 mm.

To the applicant's knowledge, the efficiency of known pulse-laser devices for cold ablation was only of the order of 10 W by the priority date of the present application. In this case, a pico-second laser achieves pulsing frequencies of about 4 MHz. However, a second pulse laser for cold ablation achieves pulse frequencies measured in kilohertz alone, their operating speed being lower than that of picosecond lasers in various cutting applications, for instance.

The successful use of cold-ablation lasers especially in coating applications always requires high vacuum values, typically of at least 10⁻⁶ atmospheres. The larger the amount of material in the gaseous phase, the weaker and poorer the quality of the material plasma fan formed of the material ablated from the substrate. With an adequate vacuum level, such a material plasma fan will have a height of about 30 mm-70 mm, cf. U.S. Pat. No. 6,372,103.

### SUMMARY OF THE INVENTION

This invention relates to a method for coating a body made of metal, rock, glass or plastic, in which the body is coated by laser ablation, with the body shifted in a material plasma fan ablated from a moving target in order to produce a surface having as regular quality as possible.

The invention also relates to a body made of metal, rock, glass or plastic that has been coated by laser ablation with body shifted in a material plasma fan ablated from a moving target in order to produce a surface having as regular quality as possible.

The present invention is based on the surprising observation that bodies made of metal, plastic, rock or glass having a planar or any three-dimensional design can be coated with regular quality if the object (substrate) to be coated is shifted in the material plasma fan ablated from the moving target. The invention enables the deposition of DLC coatings, metal coatings and metal oxide coatings on such bodies by using laser ablation.

### FIGURES

FIG. 1 illustrates the effect of hot ablation and cold ablation on the material to be ablated

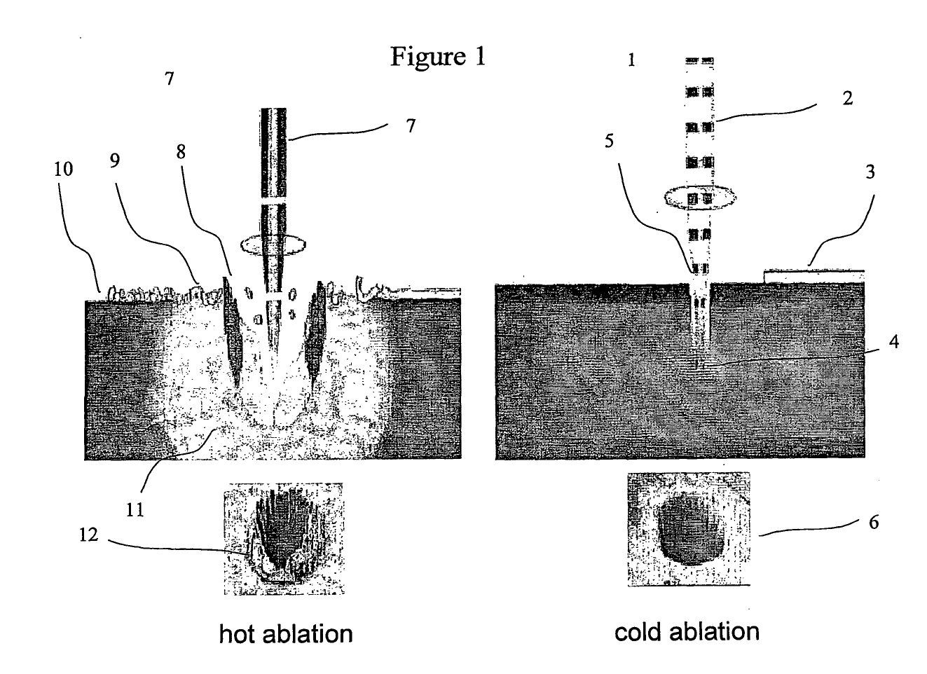

FIG. 2 illustrates a number of medical instruments coated in accordance with the invention

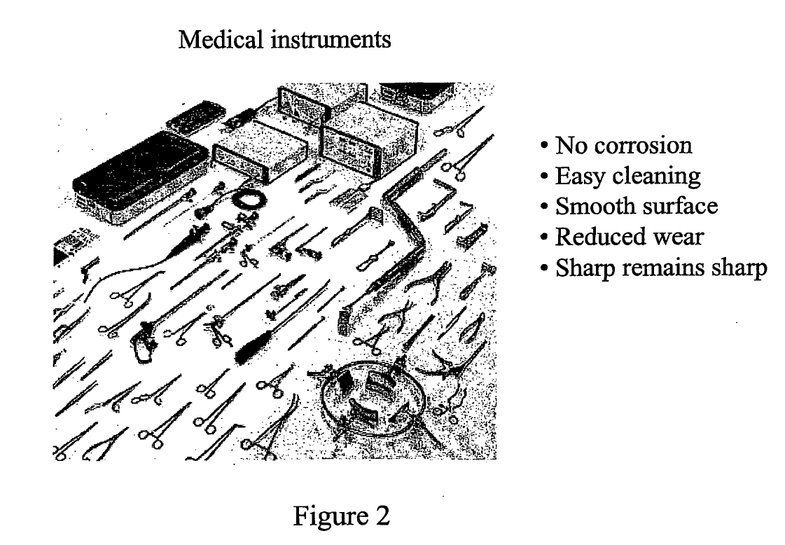

FIG. 3 illustrates a number of medical instruments coated in accordance with the invention

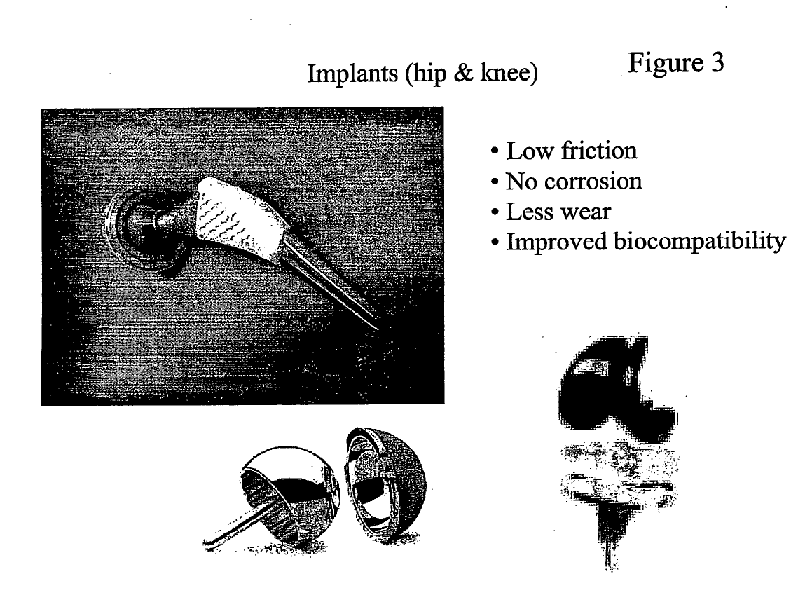

FIG. 4 illustrates a number of optical products coated in accordance with the invention

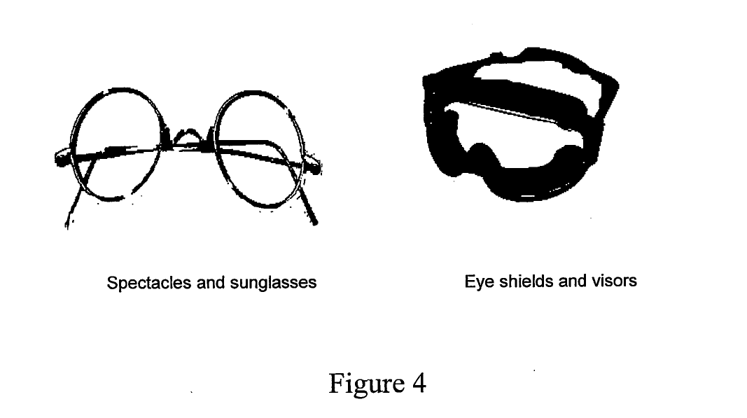

FIG. 5 illustrates a material plasma fan produced in accordance with the invention

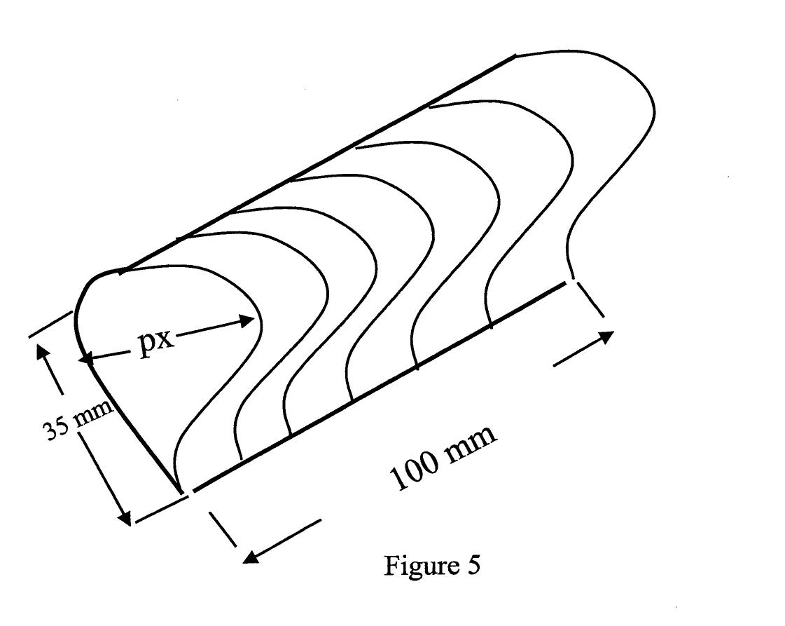

FIG. 6 illustrates the coating method of the invention. The figure illustrates the direction of movement (16) of the body (substrate) to be coated relative to the material plasma fan (17). The distance between the body to be coated and the target (material to be ablated) is 70 mm, and the angle of incidence of the laser beam on the target material body is oblique.

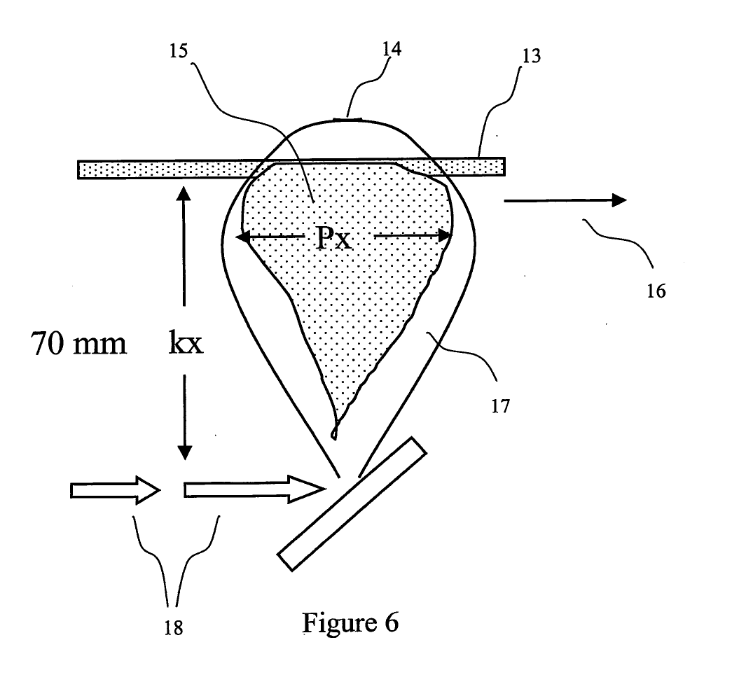

### DETAILED DESCRIPTION OF THE INVENTION

The invention relates to a method for coating a body made of metal, glass or plastic, in which the body is coated by laser ablation with the body shifted in the material plasma fan ablated from the moving target in order to produce a surface having as regular quality as possible.

In this context, a body denotes various planar and three-dimensional structures. Such structures include various metal products and their coatings, such as say, roofing sheets, interior decoration and building boards, moldings and window frames; kitchen sinks, faucets, ovens, metal coins, jewelry, tools and their parts; engines of cars and other vehicles and parts of these engines, metal plating and painted metal coatings of cars and other vehicles; metal-plated bodies used in ships, boats and aircrafts, flight turbines and combustion engines; bearings; forks, knives and spoons; scissors, sheath-knives, rotating blades, saws and all kinds of metal-plated cutters, screws and nuts; metal process apparatus used in the chemical industry, such as metal-plated reactors, pumps, distilling columns, containers and frame constructions; oil, gas and chemical pipes and various valves and control units; parts and cutters in oil drilling rigs; water transfer pipes; arms and their parts, bullets and cartridges; metal nozzles exposed to wear, such as the parts exposed to abrasion in paper machines, e.g. means for applying coating pastes; snow spades, spades and metal parts in playground toys; roadside railings, traffic signs and traffic poles; metal cans and containers; surgery instruments, artificial joints and implants and instruments; metal parts of electronic devices exposed to oxygenation and other wear, metal parts and glass and plastic lenses of cameras, and spacecrafts, including their lining solutions for withstanding friction and strong heat.

Articles produced in accordance with the invention may also include coatings and three-dimensional materials resisting corrosive chemical compounds, self-cleaning surfaces, and further anti-reflective surfaces in various lens solutions, for instance, UV protection coatings and UV active coatings used in the purification of water, solutions or air.

In accordance with the invention, the rock material can be stained in the desired colour by adding pigments or colouring agents before the final coating production by oxidation. Such a coating for colouring a rock product can be produced by laser ablation in accordance with the invention. It is also possible to produce a self-cleaning titanium dioxide coating or e.g. a strengthening and anti-scratch aluminium oxide coating on the rock material by ablating the metal oxide or the metal in the oxygen phase. This yields a resistant stone article, which is self-cleaning and even has adjustable colour if desired. Sandstone, for instance, is very susceptible to soot, and for this reason, a self-cleaning coating specifically on sandstone used on building fronts has a great economic impact.

The rock material may be any natural rock, or also ceramic in one embodiment of the invention. Typical rock types to be coated comprise facade cladding stones, such as marble and sandstone, but the method is also applicable to the coating of other stone types, such as granite, gneiss, quartzite, clay stone, etc.

The diamond coating prevents oxidation of metals and thus destruction of their decorative or other functions. In addition, a diamond surface protects underlying layers from acids and bases. The diamond coating of the invention not only protects underlying layers from mechanical wear, but also against chemical reactions. A diamond coating prevents oxidation of metals, and hence destruction of their decorative or other functions. Decorative metal plating is desired in some applications. Metals and metal compounds usable as particularly decorative targets in accordance with the invention include gold, silver, chrome, platinum, tantalum, titanium, copper, zinc, aluminium, iron, steel, zinc black, ruthenium black, cobalt, vanadium, titanium nitride, titanium aluminium nitride, titanium carbon nitride, zirconium nitride, chromium nitride, titanium silicon carbide and chrome carbide. These compounds naturally yield other properties as well, such as wear-resistant coatings or coatings that provide a shield against oxidation or other chemical reactions.

In addition, some preferred embodiments of the invention enable the production of hard and scratch-free surfaces in various glass and plastic products (lenses, large display shields, window panes in vehicles and real properties, laboratory and household glasses). In this context, particularly preferred optic coatings comprise MgF₂, SiO₂, TiO₂, Al₂O₃.

In a particularly preferred embodiment of the invention, coating is performed by means of laser ablation with a pulsed laser. The laser apparatus used for such laser ablation preferably comprises a cold-ablation laser, such as a pico-second laser.

The apparatus may also comprise a phemto-second laser, however, a pico-second laser is more advantageously used for coating.

The coating is preferably carried out under a vacuum of 10⁻⁶-10⁻¹² atmospheres.

In a preferred embodiment of the invention, the coating is performed by passing the body to be coated by two or more material plasma fans in succession. This increases the coating speed and yields a coating process more fit for industrial application. The typical distance between the structure to be coated and the target is 30 mm-100 mm, preferably 35 mm-50 mm.

In a particularly advantageous embodiment of the invention, the distance between the target and the body to be coated is maintained substantially constant over the entire ablation period.

Particularly preferred target materials include graphite, sintered carbons, metals, metal oxides and polysiloxane. Ablation of graphite or carbon allows for the production of diamond-like carbon (DLC) coatings or a diamond coating having a higher sp3/sp2 ratio.

If the target material is a metal, the metal is preferably aluminium, titanium, copper, zinc, chromium, zirconium or tin.

If it is desirable to produce a metal oxide coating, this can be done by direct ablation of metal oxide. In a second embodiment of the invention, a metal oxide coating can be produced by ablating metal in a gas atmosphere containing oxygen. The oxygen may consist of ordinary oxygen or reactive oxygen. In such an embodiment of the invention, the gas atmosphere consists of oxygen and a rare gas, preferably helium or argon, most advantageously helium.

The invention also relates to a body made of metal, plastic or glass, the body having been coated by laser ablation, with the body shifted in a material plasma fan ablated from a moving target, in order to achieve coating having as regular quality as possible.

Such a body has preferably been coated by performing the laser ablation with a pulsed laser. The laser apparatus used for ablation is then preferably a cold-ablation laser, such as a picosecond laser.

The body of the invention is preferably coated under a vacuum of 10⁻⁶-10¹² atmospheres.

In a further preferred embodiment of the invention, the body is coated by passing the plastic casing and/or lens to be coated by two or more material plasma fans in succession. The typical distance between the structure to be coated and the target is 30 mm-100 mm, preferably 35 mm-50 mm.

In a particularly advantageous embodiment of the invention, the body is coated with the distance between the target and the structure to be coated maintained substantially constant over the entire ablation period. A number of preferred target materials include graphite, sintered carbon, metals, metal oxides and polysiloxane. Preferred metals include aluminium, titanium, copper, zinc, chromium, zirconium or tin.

The body can be coated with an oxide layer also by ablating metal in a gas atmosphere into which oxygen has been introduced. Such a gas atmosphere consists of oxygen and a rare gas, preferably helium or argon, most advantageously helium.

### EXAMPLES

The method and product of the invention are described below without restricting the invention to the given examples. The coatings were produced using both X-lase 10 W pico-second laser made by Corelase Oy and X-lase 10 W picosecond laser made by Corelase Oy. Pulse energy denotes the pulse energy incident on an area of 1 square centimetre, which is focussed on an area of the desired size by means of optics.

### Example 1

In this example, a polycarbonate plate was coated with a diamond coating (of sintered carbon). The laser apparatus had the following performance parameters:

### Power 10 W

Repetition frequency 4 MHz
Pulse energy 2.5 μJ
Pulse duration 20 ps
Distance between the target and the substrate 35 mm
Vacuum level 10⁻⁷

The polycarbonate plate was thus coated with a DLC coating having a thickness of approximately 200 nm.

### Example 2

In this example, a bone screw made of roster was coated with a titanium coating. The laser apparatus had the following performance parameters and the coating was produced by ablating sintered carbon:

### Power 10 W

Repetition frequency 4 MHz
Pulse energy 2.5 μJ
Pulse duration 20 ps
Distance between the target and the substrate 37 mm
Vacuum level 10⁻⁸

The diamond coating (DLC) thus produced has a thickness of approximately 100 nm.

### Example 3

In this example, both a glass piece and a polycarbonate plate were coated with a titanium dioxide coating. The laser apparatus had the following performance parameters:

### Power 10 W

Repetition frequency 4 MHz
Pulse energy 2.5 μJ
Pulse duration 20 ps
Distance between the target and the substrate 35 mm
Vacuum level 10⁻⁸

A transparent titanium dioxide coating having an approximate thickness of 10 nm was produced both on the glass piece and the polycarbonate plate.

### Example 4

In this example, marble was coated with a titanium dioxide coating. The laser apparatus had the following performance parameters and the coating was produced by ablating titanium dioxide directly:

### Power 10 W

Repetition frequency 4 MHz
Pulse energy 2.5 μJ
Pulse duration 20 ps
Distance between the target and the substrate 28 mm
Vacuum level 10⁻⁶

A titanium dioxide coating having an approximate thickness of 100 nm was produced on the marble plate body.

### Example 5

In this example, marble was coated with a diamond coating. The stone was dried in an oven (110 C.°) for about one hour in order to remove most of the humidity contained in the stone. The laser apparatus had the following performance parameters and the coating was produced by ablating sintered carbon directly:

### Power 10 W

Repetition frequency 4 MHz
Pulse energy 2.5 μJ
Pulse duration 20 ps
Distance between the target and the substrate 30 mm
Vacuum level 10⁻⁶

A diamond coating having an approximate thickness of 200 nm was produced on the marble plate body. The light colour of the marble changed to a light beige shade, so that the natural rock pattern was visible through the coloured coating thus formed.

### Example 6

In this example, untreated sandstone was coated with titanium dioxide. The laser apparatus had the following performance parameters and the coating was produced by ablating titanium dioxide directly:

### Power 10 W

Repetition frequency 4 MHz
Pulse energy 2.5 μJ
Pulse duration 20 ps
Distance between the target and the substrate 30 mm
Vacuum level 10⁻⁶

A titanium dioxide coating having an average thickness of about 60 nm was produced on the sandstone.

1. A method for coating a body of metal, glass, rock or plastic, characterised in that the body is coated by laser ablation with the body shifted in a material plasma fan ablated from a moving target in order to achieve a coating having as regular quality as possible.

2. A method as defined in claim 1 characterised in that the laser ablation is performed using a pulsed laser.

3. A method as defined in claim 2, characterised in that the laser apparatus used for ablation is a cold-ablation laser, such as a pico-second laser.

4. A method as defined in claim 1, characterised in that laser ablation is performed under a vacuum of 10″⁶ to 10″¹² atmospheres.

5. A method as defined in claim 1 characterised in that the coating is performed by passing the body to be coated by two or more material plasma fans in succession.

6. A method as defined in claim 5, characterised in that the distance between the body to be coated and the target is in the range 30 mm to 100 mm, preferably 35 mm to 50 mm.

7. A method as defined in claim 1, characterised in that the distance between the target and the body to be coated is maintained substantially constant over the entire ablation period.

8. A method as defined in claim 1 characterised in that the target material is graphite, sintered carbon, metal, metal oxide or polysiloxane.

9. A method as defined in claim 8, characterised in that the metal is aluminium, titanium, copper, zinc, chromium, zirconium or tin.

10. A method as defined in claim 1, characterised in that an oxide coating is formed on the structure to be coated by introducing oxygen into the gas atmosphere of a vacuum chamber.

11. A method as defined in claim 10, characterised in that the gas atmosphere consists of oxygen and a rare gas, preferably helium or argon, most advantageously helium.

12. A body of metal, glass or plastic, characterised in that the body is coated by laser ablation with the body shifted in the material plasma fan ablated from a moving target in order to produce a surface having as regular quality as possible.

13. The plastic body defined in claim 12, characterised in that the laser ablation is performed with a pulsed laser.

14. The body as defined in claim 13, characterised in that the laser apparatus used for laser ablation is a cold-ablation laser, such as a pico-second laser.

15. The body defined in claims claim 12, characterised in that laser ablation is carried out under a vacuum of 10′⁶ to 10″¹² atmospheres.

16. The body defined in claim 12, characterised in that coating is performed by passing the body by two or more material plasma fans in succession.

17. The body defined in claim 16, characterised in that the distance between the body and the target is 30 mm to 100 mm, preferably 35 mm to 50 mm.

18. The body defined in claim 17, characterised in that the distance between the target and the body to be coated is maintained substantially constant over the entire ablation period.

19. The body defined in claim 12, characterised in that the target material is graphite, sintered carbon, metals, metal oxide or polysiloxane.

20. The body defined in claim 19, characterised in that the metal is aluminium, titanium, copper, zinc, chromium, zirconium or tin.

21. The body defined in claim 12, characterised in that an oxide coating has been produced on the structure to be coated by introducing oxygen into the gas atmosphere in a vacuum chamber.

22. The body defined in claim 10, characterised in that the gas atmosphere consists of oxygen and a rare gas, preferably helium or argon, most advantageously helium.
